(19) United States
(12) Patent Application Publication
(10) Pub. No.: US 2020/0202952 A1
(43) Pub. Date: Jun. 25, 2020

(54) CONTROLLER, MEMORY SYSTEM INCLUDING THE CONTROLLER, AND OPERATING METHOD OF THE MEMORY SYSTEM

(71) Applicant: SK hynix Inc., Gyeonggi-do (KR)

(72) Inventors: Keun Woo LEE, Gyeonggi-do (KR); Hye Lyoung LEE, Gyeonggi-do (KR); Yun Sik CHOI, Chungcheongbuk-do (KR)

(21) Appl. No.: 16/510,471

(22) Filed: Jul. 12, 2019

(30) Foreign Application Priority Data
Dec. 19, 2018 (KR) 10-2018-0165666

(51) Int. Cl. G11C 16/26; G06F 3/06; G06F 11/10; G11C 29/52; G11C 16/34

(52) U.S. Cl. CPC G11C 16/26; G06F 3/0659; G06F 3/0656; G06F 3/0673; G11C 16/0483; G06F 11/1068; G11C 29/52; G11C 16/349; G06F 3/0604

(57) ABSTRACT

A controller, for use in memory system, includes: a processor configured to control a read operation for a target memory area of a memory device in response to a read command received from a host; and an error correction circuit configured to perform an error correction operation on read data corresponding to the read operation, wherein the processor selects an optimum read voltage set among a plurality of read voltage sets in a read retry table, based on an erase write cycling (EW) number of the target memory area and a fail bit number of the read data.

### CROSS-REFERENCE TO RELATED APPLICATION

The present application claims priority under 35 U.S.C. § 119(a) to Korean patent application number 10-2018-0165666, filed on Dec. 19, 2018, which is incorporated herein by reference in its entirety.

### BACKGROUND

### Field of Invention

The present disclosure generally relates to an electronic device, and more particularly, to a controller, a memory system including the controller, and an operating method of the memory system.

### Description of Related Art

The paradigm for the recent computer environment has been turned into a ubiquitous computing environment in which computing systems can be used anywhere and at anytime. This promotes increasing usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A data storage device using a memory device has excellent stability and durability, high information access speed, and low power consumption, since there is no mechanical driving part. In an example of memory systems having such advantages, the data storage device includes a universal serial bus (USB) memory device, memory cards having various interfaces, and a solid state drive (SSD).

The memory device is generally classified into a volatile memory device and a nonvolatile memory device.

The nonvolatile memory device has relatively slow write and read speeds, but retains stored data even when the supply of power is interrupted. Thus, the nonvolatile memory device is used to store data o to be retained regardless of whether power is supplied.

Examples of the volatile memory include a Read Only Memory (ROM), a Mask ROM (MROM), a Programmable ROM (PROM), an Electrically Programmable ROM (EPROM), an Electrically Erasable and Programmable ROM (EEPROM), a flash memory, a Phase-change RAM is (PRAM), a Magnetic RAM (MRAM), a Resistive RAM (RRAM), and a Ferroelectric RAM (FRAM). The flash memory is classified into a NOR type flash memory and a NAND type flash memory.

### SUMMARY

Embodiments provide a controller capable of improving the accuracy of a read operation by setting an accurate read voltage in the read operation, a memory system including the controller, and an operating method of the memory system.

In accordance with an aspect of the present disclosure, there is provided a controller including: a processor configured to control a read operation for a target memory area of a memory device in response to a read command received from a host; and an error correction circuit configured to perform an error correction operation on read data corresponding to the read operation, wherein the processor selects an optimum read voltage set among a plurality of read voltage sets in a read retry table, based on an erase write cycling (EW) number of the target memory area and a fail bit number of the read data.

In accordance with another aspect of the present disclosure, there is provided a memory system including: a memory device; and a controller configured to control the memory device to perform a read operation on a target memory area of the memory device in response to a read command received from a host, wherein the controller selects an optimum read voltage set, based on an erase write cycling (EW) number is of the target memory area and a fail bit number of read data corresponding to the read operation.

In accordance with still another aspect of the present disclosure, there is provided a method for operating a memory system, the method including: determining a fail bit number by performing a read operation on a target memory area of the memory device; and selecting an optimum read voltage set among a plurality of read voltage sets in a read retry table, based on an erase write cycling (EW) number of the target memory area and the fail bit number.

### BRIEF DESCRIPTION OF THE DRAWINGS

Example embodiments will now be described more fully hereinafter with reference to the accompanying drawings; however, the example embodiments may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a memory system in is accordance with an embodiment of the present disclosure.

FIG. 2 is a block diagram illustrating a controller in accordance with an embodiment of the present disclosure.

FIG. 3 is a block diagram illustrating a read voltage setting block in accordance with an embodiment of the present disclosure.

FIG. 4 is a diagram illustrating a semiconductor memory in accordance with an embodiment of the present disclosure.

FIG. 5 is a diagram illustrating a memory block in accordance with an embodiment of the present disclosure.

FIG. 6 is a diagram illustrating an example of a three-dimensionally configured memory block.

FIG. 7 is a diagram illustrating another example of the three-dimensionally configured memory block.

FIG. 8 is a flowchart illustrating a method for establishing a correlation table of an erase write cycling number, a retention time, and an error correction code (ECC) fail bit number, and a read retry table in accordance with an embodiment of the present disclosure.

FIG. 9 is a graph illustrating a relation of an erase write cycling number, a fail bit number, and a retention time.

FIG. 10 is a table illustrating a read retry table.

FIG. 11 is a flowchart illustrating an operating method of a memory system in accordance with an embodiment of the present disclosure.

FIG. 12 is a diagram illustrating a memory system in accordance with an embodiment of the present disclosure.

FIG. 13 is a diagram illustrating a memory system in accordance with an embodiment of the present disclosure.

FIG. 14 is a diagram illustrating a memory system in accordance with an embodiment of the present disclosure.

FIG. 15 is a diagram illustrating a memory system in accordance with an embodiment of the present disclosure.

### DETAILED DESCRIPTION

The specific structural or functional description disclosed herein is merely illustrative for the purpose of describing embodiments in accordance with the concept of the present disclosure. The embodiments in accordance with the concept of the present disclosure can be implemented in various forms, and cannot be construed as limited to the embodiments set forth herein.

The embodiments in accordance with the concept of the present disclosure can be variously modified and have various shapes. Thus, the embodiments are illustrated in the drawings and are intended to be described herein in detail. However, the embodiments in accordance with the concept of the present disclosure are not construed as limited to o specified disclosures, and include all changes, equivalents, or substitutes that do not depart from the spirit and technical scope of the present disclosure.

While terms such as “first” and “second” may be used to describe various components, such components must not be understood as being is limited to the above terms. The above terms are used only to distinguish one component from another. For example, a first component may be referred to as a second component without departing from the scope of the present disclosure, and likewise a second component may be referred to as a first component.

It will be understood that when an element is referred to as being “connected” or “coupled” to another element, it can be directly connected or coupled to the other element or intervening elements may also be present. In contrast, when an element is referred to as being “directly connected” or “directly coupled” to another element, no intervening elements are present. Meanwhile, other expressions describing relationships between components such as “˜between,” “immediately ˜between” or “adjacent to ˜” and “directly adjacent to ˜” may be construed similarly.

The terms used in the present application are merely used to describe particular embodiments, and are not intended to limit the present disclosure. Singular forms in the present disclosure are intended to include the plural forms as well, unless the context clearly indicates otherwise. It will be further understood that terms such as “including” or “having,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

So far as not being differently defined, all terms used herein including technical or scientific terminologies have meanings that are commonly understood by those skilled in the art to which the present disclosure pertains. The terms having the definitions as defined in the dictionary should be understood such that the terms have meanings consistent with the context of the related technique. So far as not being clearly defined in this application, terms should not be understood in an ideally or excessively formal way.

In describing those embodiments, description will be omitted for techniques that are well known to the art to which the present disclosure pertains, and are not directly related to the present disclosure. This intends to disclose the gist of the present disclosure more clearly by omitting unnecessary description.

Hereinafter, exemplary embodiments of the present disclosure will be described in detail with reference to the accompanying drawings in order for those skilled in the art to be able to readily implement the technical spirit of the present disclosure.

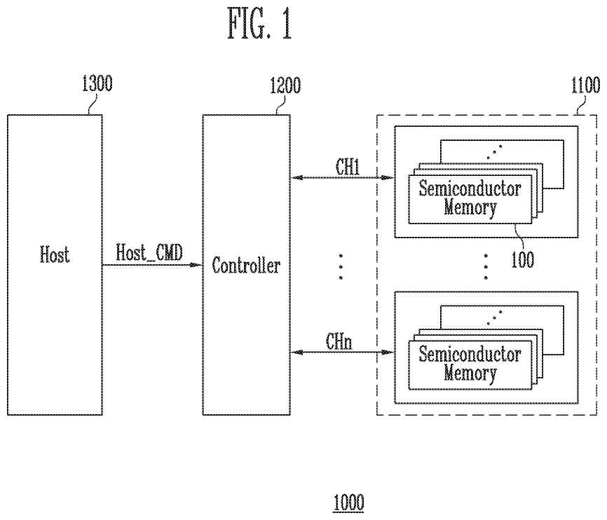

FIG. 1 is a block diagram illustrating a memory system in accordance with an embodiment of the present disclosure.

Referring to FIG. 1, the memory system 1000 includes a memory device 1100, a controller 1200, and a host 1300. The memory device 1100 includes a plurality of semiconductor memories 100. The plurality of semiconductor memories 100 may be divided into a plurality of groups. A case where the host 1300 is included in the memory system 1000 is illustrated and described in the embodiment of the present disclosure.

Alternatively, the memory system 1000 may include only the controller 1200 and the memory device 1100, and the host 1300 may be disposed at the outside of the memory system 1000.

The plurality of groups of the memory device 1100 communicate with the controller 1200, respectively, through first to nth channels CH1 to CHn. Each semiconductor memory 100 will be described later with reference to FIG. 4.

Each of the plurality of groups configured with the semiconductor memories 100 communicates with the controller 1200 through one common channel. The controller 1200 controls the plurality of semiconductor memories 100 of the memory device 1100 through the plurality of channels CH1 to CHn.

The controller 1200 is coupled between the host 1300 and the memory device 1100. The controller 1200 accesses the memory device 1100 in response to a request from the host 1300. For example, the controller 1200 controls read, write, erase, and background operations of the memory device 1100 in response to a host command Host_CMD received from the host 1300. In the write operation, the host 1300 may transmit data and an address together with the host command Host_CMD.

In the read operation, the host 1300 may transmit an address together with the host command Host_CMD. The controller 1200 provides an interface between the memory device 1100 and the host 1300. The controller 1200 drives firmware for controlling the memory device 1100.

In a power-on operation of the memory system 1000 or when a read request is received from the host 1300, the controller 1200 may perform a read voltage setting operation. In the read voltage setting operation, the controller 1200 predicts a retention time of a target memory area in the memory device 1100, based on an erase write cycling (EW) number of the target memory area and an error correction code (ECC) fail bit number according to a result obtained by performing a read operation on the target memory area. The retention time means a time until now after a program operation on the target memory area is performed. The target memory area may include all the semiconductor memories 100 of the memory device 1100, and correspond to at least one semiconductor memory among the plurality of semiconductor memories 100 or at least one memory block among a plurality of memory blocks in a selected semiconductor memory 100. Further, the memory controller 1200 selects an optimum read voltage set, based on the predicted retention time and the EW number of the target memory area, and controls the memory device 1100 to perform a read operation using a read retry scheme by using the selected read voltage set.

The host 1300 includes portable electronic devices such as a computer, a personal digital assistant (PDA), a portable media player (PMP), an MP3 player, a camera, a camcorder, and a mobile phone. The host 1300 may request a write operation, a read operation, and an erase operation of the memory system 1000 through a host command Host_CMD. In order to perform a write operation of the memory device 1100, the host 1300 may transmit, to the controller 1200, a host command Host_CMD, data, and an address, which correspond to a write command. In order to perform a read operation of the memory device 1100, the host 1300 may transmit, to the controller 1200, a host command Host_CMD and an address, which correspond to a read command. The address may be a logical address.

The controller 1200 and the memory device 1100 may be integrated into one semiconductor device. In an exemplary embodiment, the controller 1200 and the memory device 1100 may be integrated into one semiconductor device, to constitute a memory card. For example, the controller 1200 and the memory device 1100 may be integrated into one semiconductor device, to constitute a memory card such as a personal computer (PC) card (e.g., a Personal Computer Memory Card International Association (PCMCIA) card), a Compact Flash (CF) card, a Smart Media Card (e.g., SM or SMC), a memory stick, a Multi-Media Card (e.g., MMC, RS-MMC or MMCmicro), a secure digital (SD) card (e.g., SD, miniSD, microSD or SDHC), or a Universal Flash Storage (UFS).

The controller 1200 and the memory device 1100 may be integrated into one semiconductor device to constitute a semiconductor drive (e.g., a solid state drive (SSD)). The semiconductor drive includes a storage device configured to store data in a semiconductor memory.

In another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multi-Media Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the memory device 1100 or the memory system 1000 may be packaged in various forms. For example, the memory device 1100 or the memory system 1000 may be packaged in a manner such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), Plastic Metric Quad Flat Pack (PMQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi-Chip Package (MCP), Wafer-level Fabricated Package (WFP), or Wafer-level processed Stack Package (WSP).

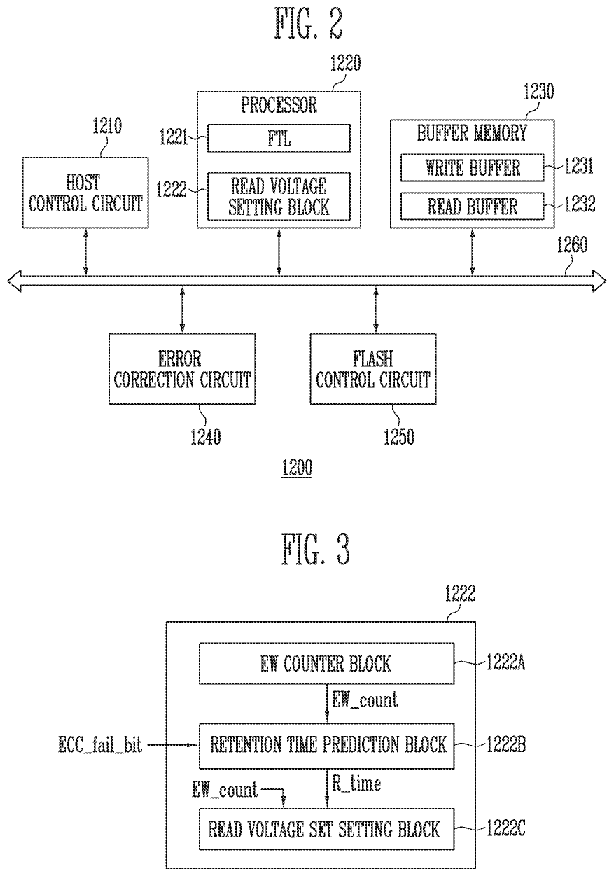

FIG. 2 is a block diagram illustrating a controller in accordance with an embodiment of the present disclosure, for example, the controller 1200 shown in FIG. 1.

Referring to FIG. 2, the controller 1200 may include a host control circuit 1210, a processor 1220, a buffer memory 1230, an error correction circuit 1240, a flash control circuit 1250, and a bus 1260.

The bus 1260 may provide a channel between components of the controller 1200.

The host control circuit 1210 may control data transmission between a host (e.g., the host 1300 of FIG. 1) and the buffer memory 1230. In an example, the host control circuit 1210 may control an operation of buffering data received from the host 1300 to the buffer memory 1230. In another example, the host control circuit 1210 may control an operation of outputting the data buffered in the buffer memory 1230 to the host 1300.

The host control circuit 1210 may include a host interface.

The processor 1220 may control the overall operations of the controller 1200, and perform a logical operation. The processor 1220 may communicate with the host 1300 through the host control circuit 1210, and communicate with a memory device (e.g., the memory device 1100 of FIG. 1) through the flash control circuit 1250. The processor 1220 may control an operation of a memory system (e.g., the memory system 1000 of FIG. 1) by using the buffer memory 1230 as a working memory, cache memory, or buffer memory. The processor 1220 may control the flash control circuit 1250 in response to a command queue, which is generated by realigning a plurality of host commands received from the host 1300 according to an order of priority. In a power-on operation, when a read request is received from the host 1300, or after a set time elapses from when a read operation is performed, the processor 1220 may perform a read voltage setting operation.

The processor 1220 may include a flash translation layer (FTL) 1221 and a read voltage setting block 1222.

The FTL 1221 controls overall operations of the memory system 1000 by driving firmware. The firmware may be stored in an additional memory (not shown) directly coupled to the buffer memory 1230 or a storage space of the processor 1220. In a write operation, the FTL 1221 may map a corresponding physical address to an address (e.g., a logical address) which is received from the host 1300. In a read operation, the FTL 1221 checks the physical address mapped to the logical address.

The FTL 1221 may generate a command queue for controlling the flash control circuit 1250 in response to a host command received from the host 1300.

The read voltage setting block 1222 performs a read voltage setting operation. The read voltage setting operation may be performed during a power-on operation of the memory system 1000. Alternatively, the read voltage setting operation may be performed when a request is received from the host 1300. The read voltage setting block 1222 predicts a retention time of a target memory area, based on an erase write cycling (EW) number of the target memory area and an error correction code (ECC) fail bit number according to a result obtained by performing a read operation on the target memory area, in the read voltage setting operation. Also, the read voltage setting block 1222 selects an optimum read voltage set in a read retry table (RRT), based on the predicted retention time and the EW number of the target memory area. Further, the read voltage setting block 1222 controls the memory device 1100 to perform a read retry operation using the selected read voltage set. The RRT may be stored in a system memory block or Content Addressable Memory (CAM) block in the memory device 1100. The RRT may be read in a power-on operation of the memory device 1100 to be stored in the buffer memory 1230.

The buffer memory 1230 may be used as a working memory, cache memory or data buffer memory of the processor 1220. The buffer memory 1230 may store codes and commands, which are executed by the processor 1220. The buffer memory 1230 may store data processed by the processor 1220. Also, the buffer memory 1230 may receive and store the RRT read from the system memory block or CAM block of the memory device 1100 in the power-on operation of the memory device 1100.

The buffer memory 1230 may include a write buffer 1231 and a read buffer 1232. In a write operation, the write buffer 1231 temporarily stores data received from the host 1300 and then transmits the temporarily stored data to the memory device 1100 when an internal command corresponding to the write operation is transmitted to the memory device 1100. In a read operation, the read buffer 1232 temporarily stores data received from the memory device 1100 and then transmits the temporarily stored data to the host 1300.

The buffer memory 1230 may include a static RAM (SRAM) or dynamic RAM (DRAM).

The error correction circuit 1240 may perform error correction. The error correction circuit 1240 may perform ECC encoding, based on data to be written to the memory device 1100 through the flash control circuit 1250. The ECC-encoded data may be transferred to the memory device 1100 through the flash control circuit 1250. The error correction circuit 1240 may perform ECC decoding on data received from the memory device 1100 through the flash control circuit 1250. The error correction circuit 1240 may detect and count ECC fail bits of data received from the memory device 1100 in a read operation, and transmit the counted ECC fail bit number to the processor 1220.

In an example, the error correction circuit 1240 may be included as an internal component of the flash control circuit 1250.

The flash control circuit 1250 generates and outputs an internal command for controlling the memory device 1100 in response to the command queue generated by the processor 1220. In a write operation, the flash control circuit 1250 may control the write operation by transmitting data buffered to the write buffer 1231 to the memory device 1100. Ina read operation, the flash control circuit 1250 may control an operation of buffering data read from the memory device 1100 to the read buffer 1232 in response to a command queue. Also, in a read operation, the flash control circuit 1250 may perform an operation of transmitting, to the processor 1220, fail bits of data received from the memory device 1100.

The flash control circuit 1250 may include a flash interface.

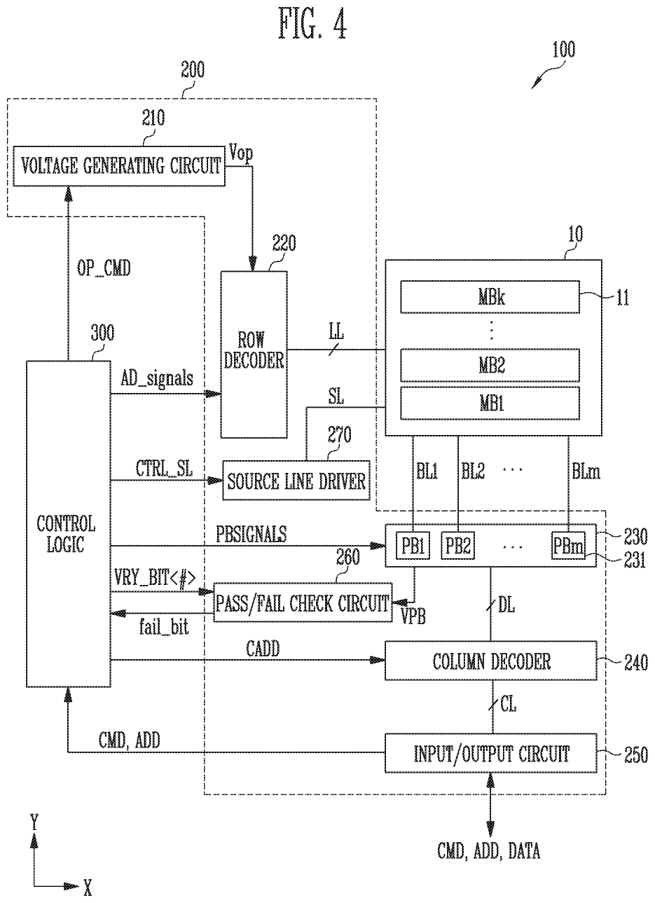

FIG. 3 is a block diagram illustrating a read voltage setting block in accordance with an embodiment of the present disclosure, for example, the read voltage setting block 1222 shown in FIG. 2.

Referring to FIG. 3, the read voltage setting block 1222 may include an erase writing (EW) counter block 1222A, a retention time prediction block 1222B, and a read voltage set setting block 1222C.

The EW counter block 1222A counts and stores an erase writing counting (EW) number for a target memory area of a memory device (e.g., the memory device 1100 of FIG. 1). Further, the EW counter block 1222A outputs the stored EW number EW_count in a read voltage setting operation.

The retention time prediction block 1222B predicts a retention time R_time, based on ECC fail bits ECC_fail_bit and the EW number EW_count. The ECC fail bits ECC_fail_bit may be detected and counted when the error correction circuit 1240 of FIG. 2 performs an error correction operation on read data, which is the result obtained by performing a test read operation.

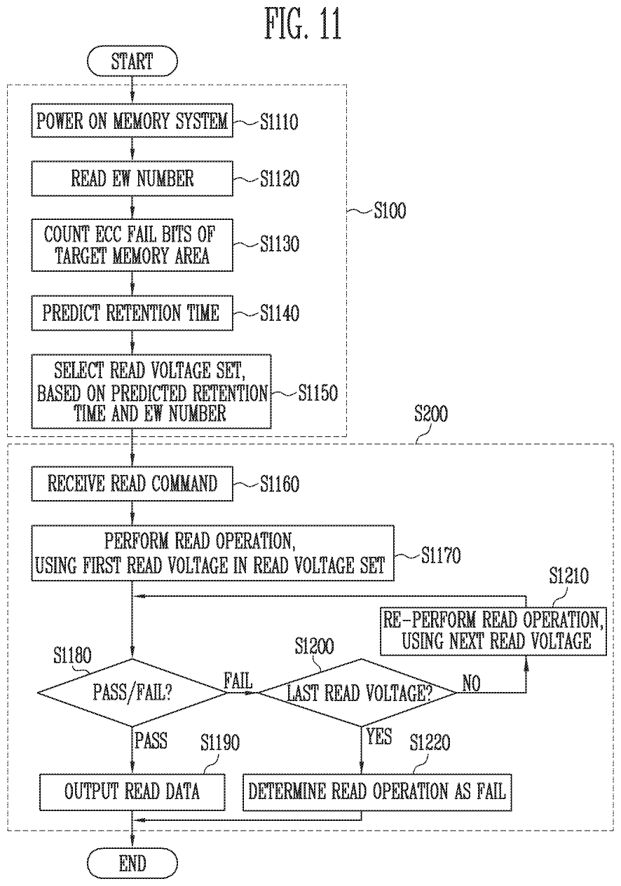

A method for predicting the retention time R_time will be described in detail with reference to FIG. 11.

The read voltage set setting block 1222C selects one read voltage set among a plurality of read voltage sets in a read retry table (RRT), based on the retention time R_time and the EW number EW_count. Further, the read voltage set setting block 1222C sets a read voltage for the read operation of the memory device 1100 using the selected read voltage set.

FIG. 4 is a diagram illustrating a semiconductor memory in accordance with an embodiment of the present disclosure, for example, the semiconductor memory 100 shown in FIG. 1.

Referring to FIG. 4, the semiconductor memory 100 may include a memory cell array 10 for storing data. The semiconductor memory 100 may include a peripheral circuit 200 configured to perform a program operation for storing data in the memory cell array 10, a read operation for outputting the stored data, and an erase operation for erasing the stored data. The semiconductor memory 100 may include a control logic 300 that controls the peripheral circuit 200 under the control of a controller (e.g., the controller 1200 shown in FIG. 1).

The memory cell array 10 may include a plurality of memory blocks MB1 to MBk including a memory block MBk (where k is a positive integer). Local lines LL and bit lines BL1 to BLm (where m is a positive integer) may be coupled to the memory blocks MB1 to MBk 11. For example, the local lines LL may include a first select line, a second select line, and a plurality of word lines arranged between the first and second select lines. The local lines LL may further include dummy lines arranged between the first select line and the word lines and between the second select line and the word lines. The first select line may be a source select line, and the second select line may be a drain select line. For example, the local lines LL may include word lines, drain and source select lines, and source lines SL. The local lines LL may further include dummy lines. The local lines LL may further include pipe lines. The local lines LL may be coupled to the memory blocks MB1 to MBk 11, respectively. The bit lines BL1 to BLm may be commonly coupled to the memory blocks MB1 to MBk 11. The memory blocks MB1 to MBk 11 may be implemented in a two-dimensional or three-dimensional structure. For memory blocks 11 having a two-dimensional structure, memory cells may be arranged in a direction parallel to a substrate. For memory blocks 11 having a three-dimensional structure, memory cells may be arranged in a direction vertical to a substrate. At least one memory block (e.g., MB1) among the memory blocks MB1 to MBk may be defined as a system memory block or content addressable memory (CAM) block, and the system memory block or CAM block may store a read retry table (RRT) and a correlation table of an erase write cycling (EW) number, a retention time, and an error correction code (ECC) fail bit number.

The peripheral circuit 200 may be configured to perform program, read, and erase operations of a selected memory block 11 under the control of the control logic 300. The peripheral circuit 200 may include a voltage generating circuit 210, a row decoder 220, a page buffer group 230, a column decoder 240, an input and output (input/output) circuit 250, a pass and fail (pass/fail) check circuit 260, and a source line driver 270.

The voltage generating circuit 210 may generate various operating voltages Vop used for program, read, and erase operations in response to an operation signal OP_CMD. The voltage generating circuit 210 may selectively discharge the local lines LL in response to the operation signal OP_CMD. For example, the voltage generating circuit 210 may generate a program voltage, a verify voltage, a pass voltage, and a select transistor operation voltage under the control of the control logic 300.

The row decoder 220 may transfer the operating voltages Vop to local lines LL coupled to the selected memory block 11 in response to control signals AD_signals. For example, the row decoder 220 may selectively apply operating voltages (e.g., a program voltage, a verify voltage, and a pass voltage) to word lines among the local lines LL in response to the control signals AD_signals.

In a program voltage applying operation, the row decoder 220 applies a program voltage to a selected word line among the local lines LL in the control signals AD_signals, and applies a pass voltage to other unselected word lines. In a read operation, the row decoder 220 applies a read voltage to a selected word line among the logical lines LL in response to the control signals AD_signals, and applies a pass voltage to other unselected word lines.

The page buffer group 230 may include a plurality of page buffers PB1 to PBm 231 coupled to the bit lines BL1 to BLm. The page buffers PB1 to PBm 231 may operate in response to page buffer control signals PBSIGNALS. In a program operation, the page buffers PB1 to PBm 231 may temporarily store data to be programmed. In a read or verify operation, the page buffers PB1 to PBm 231 may sense voltages or currents of the bit lines BL1 to BLm.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are received from the controller 1200 of FIG. 1, to the control logic 300, or exchange data DATA with the column decoder 240.

In a read operation, the pass/fail check circuit 260 may generate a reference current in response to a allow bit VRY_BIT<#>. Further, the pass/fail check circuit 260 may output a pass signal PASS or a fail signal FAIL by comparing a sensing voltage VPB received from the page buffer group 230 with a reference voltage generated by the reference current.

The source line driver 270 may be coupled to a memory cell included in the memory cell array 10 through a source line SL, and control a voltage applied to the source line SL. The source line driver 270 may receive a source line control signal CTRL_SL from the control logic 300, and control a source line voltage applied to the source line SL, based on the source line control signal CTRL_SL.

The control logic 300 may control the peripheral circuit 200 by outputting the operation signal OP_CMD, the control signals AD_signals, the page buffer control signals PBSIGNALS, and the allow bit VRY_BIT<#> in response to the command CMD and the address ADD. Also, the control logic 300 may determine whether the verify operation has passed or failed in response to the pass or fail signal PASS or FAIL.

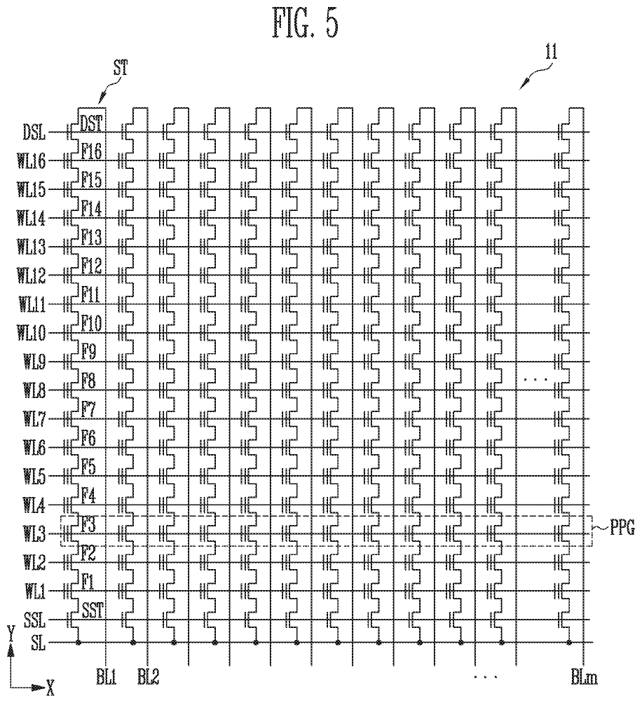

FIG. 5 is a diagram illustrating a memory block in accordance with an embodiment of the present disclosure, for example, the memory block 11 shown in FIG. 4.

Referring to FIG. 5, in the memory block 11, a plurality of word lines arranged in parallel to one another may be coupled between a first select line and a second select line. The first select line may be a source select line SSL, and the second select line may be a drain select line DSL. More specifically, the memory block 11 may include a plurality of strings ST coupled between bit lines BL1 to BLm and a source line SL. The bit lines BL1 to BLm may be coupled to the strings ST, respectively. The source line SL may be commonly coupled to the strings ST. The strings ST may be configured identically to one another, and therefore, a string ST coupled to a first bit line BL1 will be described in detail as an example.

The string ST may include a source select transistor SST, a plurality of memory cells F1 to F16, and a drain select transistor DST, which are coupled in series to each other between the source line SL and the first bit line BL1, The string ST may include at least one source select transistor SST and at least one drain select transistor DST. The string ST may include a number of memory cells greater than that of the number of memory cells F1 to F16.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of source select transistors SST in different strings ST may be coupled to the source select line SSL, gates of drain select transistors DST in different strings ST may be coupled to the drain select line DSL. Gates of the memory cells F1 to F16 in different strings ST may be coupled to a plurality of word lines WL1 to WL16. A group of memory cells coupled to the same word line among the memory cells in different strings ST may be a physical page PPG. Therefore, the memory block 110 may include a number of physical pages PPG which corresponds to the number of word lines WL1 to WL16.

One memory cell may store data of one bit. The one memory cell is generally referred to as a single level cell (SLC). One physical page PPG may store one logical page (LPG) data. The one LPG data may include data bits corresponding to the number of cells in one physical page PPG. Also, one memory cell may store data of two or more bits. The one memory cell is generally referred to as a multi-level cell (MLC). One physical page PPG may store two or more LPG data.

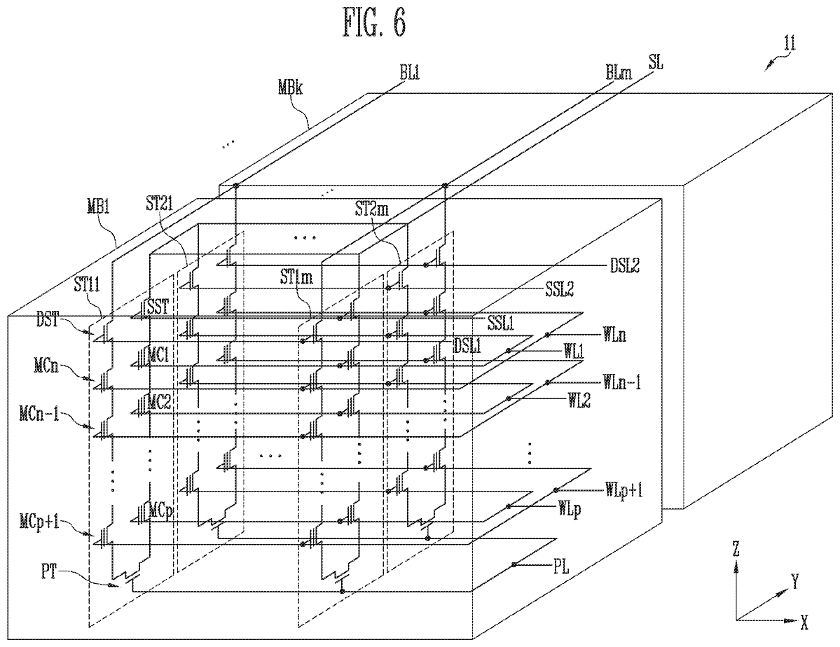

FIG. 6 is a diagram illustrating an example of a three-dimensionally configured memory block 11 of the memory cell array 10.

Referring to FIG. 6, the memory cell array 10 may include memory blocks MB1 to MBk including the memory block 11. The memory block 11 may include a plurality of strings ST11 to ST1m and ST21 to ST2m. In an embodiment, each of the plurality of strings ST11 to ST1m and ST21 to ST2m may be formed in a ‘U’ shape. In the memory block 11, strings may be arranged in a row direction (e.g., X direction). Although FIG. 6 illustrates a case where two strings are arranged in a column direction (e.g., Y direction), three or more strings may be arranged in the column direction (e.g., Y direction).

Each of the plurality of strings ST11 to ST1m and ST21 to ST2m may include at least one source select transistor SST, first to nth memory cells MC1 to MCn, a pipe transistor PT, and at least one drain select transistor DST.

The source and drain select transistors SST and DST and the memory cells MC1 to MCn may have structures similar to one another. Each of the source and drain select transistors SST and DST and the memory cells MC1 to MCn may include a channel layer, a tunnel insulating layer, a charge trapping layer, and a blocking insulating layer. For example, a pillar for providing the channel layer may be provided in each string. For another example, a pillar for providing at least one of the channel layer, the tunnel insulating layer, the charge trapping layer, and the blocking insulating layer may be provided in each string.

The source select transistor SST of each string may be coupled between a source line SL and memory cells MC1 to MCp.

In an embodiment, source select transistors of strings arranged in the same row may be coupled to a source select line extending in the row direction, and source select transistors of strings arranged in different rows may be coupled to different source select lines. In FIG. 6, source select transistors of strings ST11 to ST1m of a first row may be coupled to a first source select line SSL1. Source select transistors of strings ST21 to ST2m of a second row may be coupled to a second source select line SSL2.

In another embodiment, the source select transistors of the strings ST11 to ST1m and ST21 to ST2m may be commonly coupled to one source select line.

First to nth memory cells MC1 to MCn of each string may be coupled between the source select transistor SST and the drain select transistor DST.

The first to nth memory cells MC1 to MCn may be divided into first to pth memory cells MC1 to MCp and (p+1)th to nth memory cells MCp+1 to MCn. The first to pth memory cells MC1 to MCp may be sequentially arranged in a vertical direction (e.g., Z direction), and be coupled in series to each other between the source select transistor SST and the pipe transistor PT. The (p+1)th to nth memory cells MCp+1 to MCn may be sequentially arranged in the vertical direction (e.g., Z direction), and be coupled in series to each other between the pipe transistor PT and the drain select transistor DST. The first to pth memory cells MC1 to MCp and the (p+1)th to nth memory cells MCp+1 to MCn may be coupled to each other through the pipe transistor PT. Gates of the first to nth memory cells MC1 to MCn of each string may be coupled to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. A gate of the pipe transistor PT of each string may be coupled to a pipe line PL.

The drain select transistor DST of each string may be coupled to a bit line and the memory cells MCp+1 to MCn. Strings arranged in the row direction may be coupled to a drain select line extending in the row direction. Drain select transistors of the strings ST11 to ST1 of the first row may be coupled to a first drain select line DSL1. Drain select transistors of the strings ST21 to ST2m of the second row may be coupled to a second drain select line DSL2.

Strings arranged in the column direction may be coupled to bit lines extending in the column direction. In FIG. 6, strings ST11 and ST21 of a first column may be coupled to a first bit line BL1. Strings ST1m and ST2m of an mth column may be coupled to an mth bit line BLm.

Memory cells coupled to the same word line among the strings arranged in the row direction may constitute one page. For example, memory cells coupled to the first word line WL1 among the strings ST11 to ST1m of the first row may constitute one page. Memory cells coupled to the first word line WL1 among the strings ST21 to ST2m of the second row may constitute another page. When any one of the drain select lines DSL1 and DSL2 is selected, strings arranged in one row direction may be selected. When any one of the word lines WL1 to WLn is selected, one page among the selected strings may be selected.

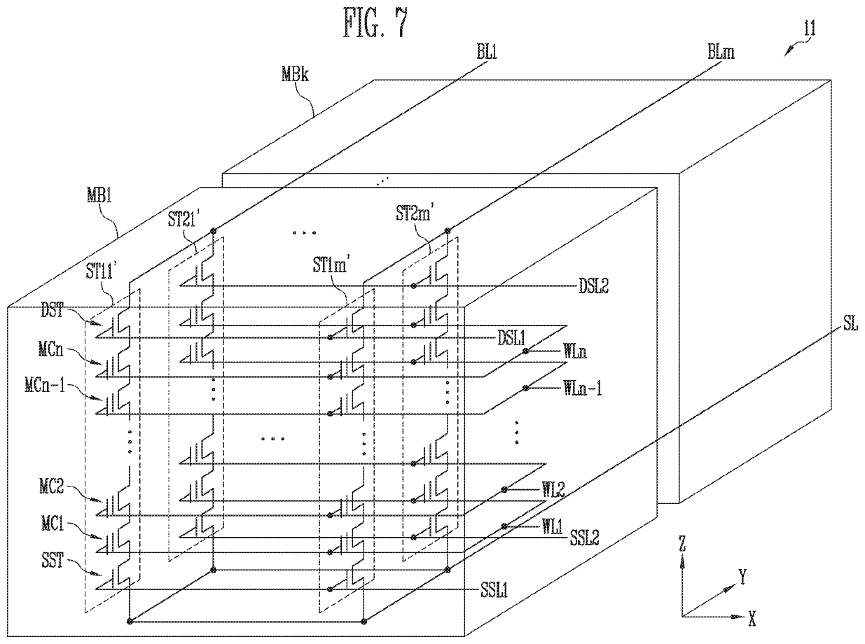

FIG. 7 is a diagram illustrating another example of the three-dimensionally configured memory block 11 in the memory cell array 10.

Referring to FIG. 7, the memory cell array 10 may include a plurality of memory blocks MB1 to MBk including the memory block 11. The memory block 11 may include a plurality of strings ST11′ to ST1m′ and ST21′ to ST2m′. Each of the plurality of strings ST11′ to ST1m′ and ST21′ to ST2m′ may extend along a vertical direction (e.g., Z direction). In the memory block 11, m strings may be arranged in a row direction (e.g., X direction). Although FIG. 7 illustrates a case where two strings are arranged in a column direction (e.g., Y direction), three or more strings may be arranged in the column direction (e.g., Y direction).

Each of the plurality of strings ST11′ to ST1m′ and ST21′ to ST2m′ may include at least one source select transistor SST, first to nth memory cells MC1 to MCn, and at least one drain select transistor DST.

The source select transistor SST of each string may be coupled between a source line SL and the memory cells MC1 to MCn. Source select transistors of strings arranged in the same row may be coupled to the same source select line. Source select transistors of strings ST11′ to ST1m′ arranged on a first row may be coupled to a first source select line SSL1. Source select transistors of strings ST21′ to ST2m′ arranged on a second row may be coupled to a second source select line SSL2. In another embodiment, the source select transistors of the strings ST11′ to ST1m′ and ST21′ to ST2m′ may be commonly coupled to one source select line.

The first to nth memory cells MC1 to MCn of each string may be coupled in series to each other between the source select transistor SST and the drain select transistor DST. Gates of the first to nth memory cells MC1 to MCn may be coupled to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. Accordingly, the reliability of data stored in the memory block 11 can be improved.

The drain select transistor DST of each string may be coupled between a bit line and the memory cells MC1 to MCn. Drain select transistors DST of strings arranged in the row direction may be coupled to a drain select line extending in the row direction. The drain select transistors DST of the strings ST11′ to ST1m′ of the first row may be coupled to a first drain select line DSL1. The drain select transistors DST of the strings ST21° to ST2m′ of the second row may be coupled to a second drain select line DSL2.

FIG. 8 is a flowchart illustrating a method for establishing a correlation table of an erase write cycling (EW) number, a retention time, and an error correction code (ECC) fail bit number, and a read retry table (RRT) in accordance with an embodiment of the present disclosure.

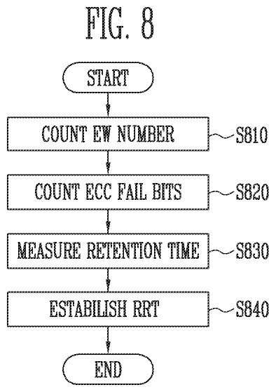

FIG. 9 is a graph illustrating a relationship of an erase write cycling (EW) number, a fail bit number, and a retention time.

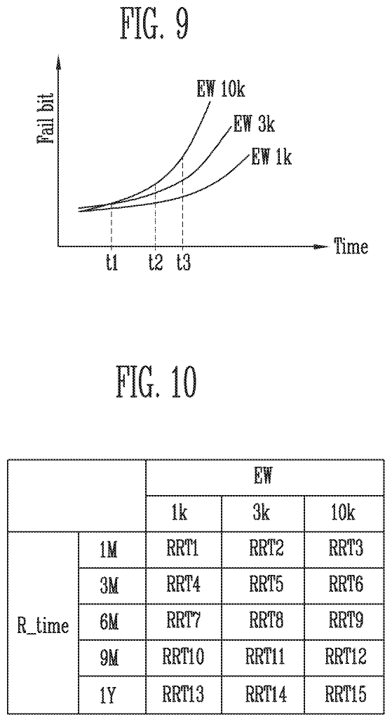

FIG. 10 is a table illustrating a read retry table (RRT).

A method for establishing an RRT in accordance with an embodiment of the present disclosure will be described as follows with reference to FIGS. 1 to 10.

Referring to FIG. 8, an erase operation and a write operation are repeatedly performed a first set number of times (e.g., 1K or 1000) on a target memory area of the memory device 1100, and an erase write cycling (EW) number is counted (S810).

After a first time t1 elapses from when the last write operation is performed, a read operation on the target memory area is performed, and ECC fail bits of read data are counted by performing an error correction operation on the read data (S820). The first time t1 is measured as a retention time R_time (S830).

In addition, after a second time t2 elapses from when the last write operation is performed as shown in FIG. 9, a read operation on the target memory area is performed, and ECC fail bits of read data are counted by performing an error correction operation on the read data. The second time t2 is greater than the first time t1 as shown in FIG. 9.

In addition, after a third time t3 elapses from when the last write operation is performed, a read operation on the target memory area is performed as shown in FIG. 9, and ECC fail bits of read data are counted by performing an error correction operation on the read data. The third time t3 is greater than the second time t2 as shown in FIG. 9.

An ECC fail bit number of each of the first to third times t1 to t3 is counted for a first EW number (1K) as the result of the above-described steps.

In the present disclosure, as shown in FIG. 9, the retention time R_time includes the first to third times t1 to t3. However, the present disclosure is not limited thereto, and the retention time R_time may include multiple times, which are divided in units of months or years.

An erase operation and a write operation are repeatedly performed a second set number of times (e.g., 3K or 3000) on the target memory area of the memory device 1100, and the above-described steps S810 to S830 are re-performed. As a result, an ECC fail bit number of each of the first to third times t1 to t3 is counted for a second EW number (3K).

In addition, an erase operation and a write operation are repeatedly performed a third set number of times (e.g., 10K or 10000) on the target memory area of the memory device 1100, and the above-described steps S810 to S830 are re-performed. As a result, an ECC fail bit number of each of the first to third times t1 to t3 is counted for a third EW number (10K).

As shown in FIG. 9, in the memory cells of the memory device, the ECC fail bit number increases when the EW number increases and the retention time increases. A correlation table of the EW number, the retention time, and the ECC fail bit number may be established according to the above-described operation result.

As shown in FIG. 10, a read retry table (RRT) including read voltage sets RRT1 to RRT15 is established based on the EW number and the ECC fail bit number for each of the first to third times t1 to t3, which are obtained as the above-described operation result.

For example, a first read voltage set RRT1 is set based on an ECC fail bit number, which is measured after the retention time R_time of one month (1M) elapses from when the EW number is 1K. A fifteenth read voltage set RRT15 is set based on an ECC fail bit number, which is measured after the retention time R_time of one year (1Y) elapses from when the EW number is 10K.

As described above, an RRT including a read voltage set optimized under each condition is established by measuring ECC fail bit numbers with respect to a plurality of retention times and a plurality of EW numbers.

The above-described correlation table of the EW number, the retention time, and the ECC fail bit number, and the above-described RRT may be stored in the system memory block or CAM block of the memory device 1100.

FIG. 11 is a flowchart illustrating an operating method of a memory system in accordance with an embodiment of the present disclosure, for example, the memory system 1000 of FIG. 1.

The operating method of the memory system in accordance with the embodiment of the present disclosure will be described as follows with reference to FIGS. 1 to 7 and 9 to 11.

Referring to FIG. 11, the operating method of FIG. 11 may include a read voltage setting step S100 and a read operation step S200.

The read voltage setting step S100 may include steps S1110 to S1150.

When the memory system 1000 is power-on (S1110), a correlation table and an RRT are read and loaded into the buffer memory 1230. The correlation table stores information of an EW number, a retention time, and an ECC fail bit number.

The EW counter block 1222A of the read voltage setting block 1222 reads, from the correlation table, an EW number EW_count of a target memory area in the memory device 1100 and outputs the EW number EW_count (S1120).

The memory device 1100 outputs read data by performing a read operation on the target memory area. The error correction circuit 1240 outputs ECC fail bits ECC_fail_bit by counting fail bits of the read data (S1130).

The retention time prediction block 1222B predicts a retention time R_time, based on the ECC fail bits ECC_fail_bit of the read data on the target memory area and the EW number EW_count of the target memory area (S1140). The read data is obtained by performing the read operation on the target memory area.

For example, the retention time R_time is predicted using the ECC fail bits ECC_fail_bit and the EW number EW_count, based on the correlation table of the EW number, the retention time, and the ECC fail bit, which is shown in FIG. 9.

The read voltage set setting block 1222C selects one read voltage set among a plurality of read voltage sets in the RRT, based on the retention time R_time, which is predicted by the retention time prediction block 1222B and the EW number EW_count. Further, the read voltage set setting block 1222C sets a read voltage for the read operation of the memory device 1100 by using the selected voltage set (S1150).

The read operation step S200 may include steps S1160 to S1220.

When a host command Host_CMD, i.e., a read command corresponding to a read request from the host 1300 (S1160), the processor 1220 of the controller 1200 generates a command queue by queuing the received read command.

The flash control circuit 1250 generates an internal command CMD for controlling the read operation of the memory device 1100 in response to the read command queued in the command queue. Further, the flash control circuit 1250 transmits the generated internal command CMD to the memory device 1100.

The memory device 1100 performs the read operation in response to the internal command CMD received from the controller 1200 (S1170). For example, a semiconductor memory among the plurality of semiconductor memories 100 in the memory device 1100 is selected and the selected semiconductor memory performs the read operation using a read voltage in response to the received internal command CMD. The read voltage may be a first read voltage in the read voltage set that is set by the read voltage set setting block 1222C.

The error correction circuit 1240 of the controller 1200 determines a result of an error correction operation by performing the error correction operation on read data received from the memory device 1100 (S1180). For example, the error correction circuit 1240 may perform ECC decoding on the read data through the flash control circuit 1250. The ECC-decoded data may be transferred to the read buffer 1232. The correction operation may be determined as pass or fail according to the number of error bits in the read data. When the number of error bits in the read data is less than or equal to a maximum allowable error bit number of the error correction circuit 1240, the error correction circuit 1240 determines the error correction operation as pass by normally performing an ECC decoding operation. When the number of error bits in the read data is greater than the maximum allowable error bit number, the error correction circuit 1240 determines the error correction operation as fail.

When the result of the determination step S1180 is determined as pass (PASS), the read data stored in the read buffer 1232 is output to the host 1300 through the host control circuit 1210 (S1190).

When the result of the determination step S1180 is determined as fail (FAIL), the processor 1220 determines whether a read voltage used in a previous read operation is the last read voltage in the read voltage set that is set by the read voltage set setting block 1222C (S1200).

When it is determined that the read voltage is not the last read voltage as the result of the determination step S1200 (NO), the read operation is re-performed using a next read voltage in the read voltage set (S1210).

When it is determined that the read voltage is the last read voltage as the result of the determination step S1200 (YES), the read operation is determined as fail (S1210), and the operating method of the memory system 1000 is ended.

As described above, in accordance with the embodiment of the present disclosure, in a read voltage setting operation of the memory system, a retention time is predicted based on an EW number of a target memory area and an ECC fail bit, and an optimum read voltage set in the RRT is selected based on the predicted retention time and the EW number, so that the accuracy of the read operation may be improved.

FIG. 12 is a diagram illustrating a memory system 30000 in accordance with an embodiment of the present disclosure.

Referring to FIG. 12, the memory system 30000 may be implemented as a cellular phone, a smart phone, a tablet personal computer (PC), a personal digital assistant (PDA), or a wireless communication device. The memory system 30000 may include a memory device 1100 and a controller 1200 capable of controlling an operation of the memory device 1100. The controller 1200 may control a data access operation of the memory device 1100, e.g., a program operation, an erase operation, a read operation, or the like under the control of a processor 3100.

Data programmed in the memory device 1100 may be output through a display 3200 under the control of the controller 1200.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the controller 1200 or the display 3200. The controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad, a computer mouse, a keypad, or a keyboard. The processor 3100 may control an operation of the display 3200 such that data output from the controller 1200, data output from the radio transceiver 3300, or data output from the input device 3400 can be output through the display 3200.

In some embodiments, the controller 1200 capable of controlling an operation of the memory device 1100 may be implemented as a part of the processor 3100, or be implemented as a chip separate from the processor 3100. Also, the controller 1200 may be implemented with the controller shown in FIG. 2.

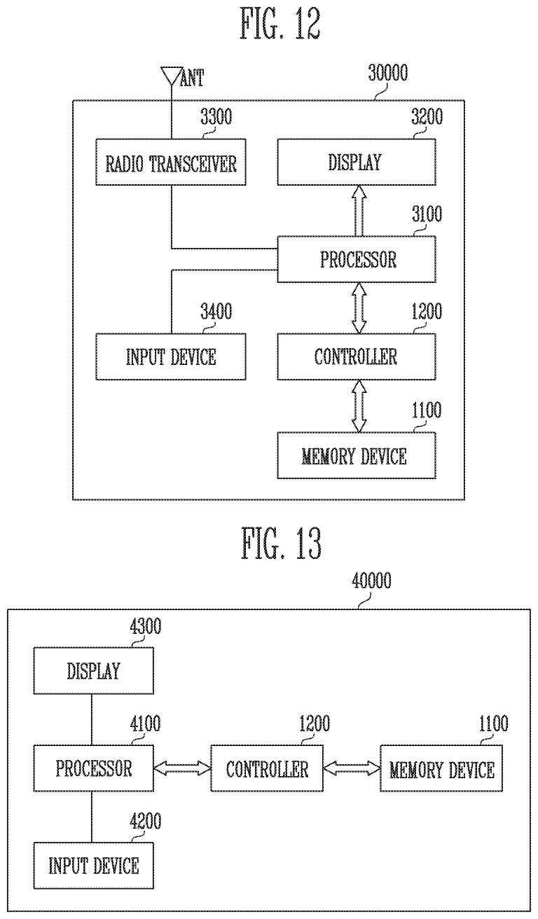

FIG. 13 is a diagram illustrating a memory system 40000 in accordance with an embodiment of the present disclosure.

Referring to FIG. 13, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the controller 1200. In some embodiments, the controller 1200 capable of controlling an operation of the memory device 1100 may be implemented as a part of the processor 4100, or be implemented as a chip separate from the processor 4100. Also, the controller 1200 may be implemented with the controller shown in FIG. 2.

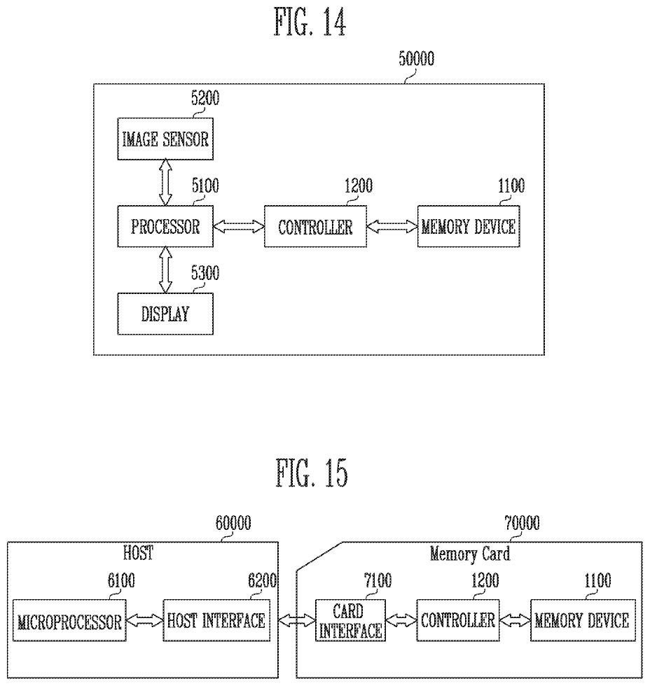

FIG. 14 is a diagram illustrating a memory system 50000 in accordance with an embodiment of the present disclosure.

Referring to FIG. 14, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the controller 1200. Under the control of the processor 5100, the converted digital signals may be output through a display 5300, or be stored in the memory device 1100 through the controller 1200. In addition, data stored in the memory device 1100 may be output through the display 5300 under the control of the processor 5100 or the controller 1200.

In some embodiments, the controller 1200 capable of controlling an operation of the memory device 1100 may be implemented as a part of the processor 5100, or be implemented as a chip separate from the processor 5100. Also, the controller 1200 may be implemented with the controller shown in FIG. 2.

FIG. 15 is a diagram illustrating a memory system 70000 in accordance with an embodiment of the present disclosure.

Referring to FIG. 15, the memory system 70000 may be implemented as a memory card or a smart card. The memory system 70000 may include a memory device 1100, a controller 1200, and a card interface 7100.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto. Also, the controller 1200 may be implemented with the controller shown in FIG. 2.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor 6100.

In accordance with the present disclosure, a retention time is predicted based on an EW number and a fail bit number, and a read voltage is set based on the predicted retention time, so that a read operation is performed using an optimum read voltage, thereby improving the accuracy of the read operation.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A controller comprising:
a processor configured to control a read operation for a target memory area of a memory device in response to a read command received from a host; and
an error correction circuit configured to perform an error correction operation on read data corresponding to the read operation,
wherein the processor selects an optimum read voltage set among a plurality of read voltage sets in a read retry table, based on an erase write cycling (EW) number of the target memory area and a fail bit number of the read data.

2. The controller of claim 1, wherein the error correction circuit detects and counts fail bits of the read data, and transmits the counted fail bit number to the processor.

3. The controller of claim 1, wherein the processor includes:
a flash translation layer configured to generate a command queue for controlling the read operation in response to the read command; and
a read voltage set setting block configured to select and set the optimum read voltage set, based on the EW number and the fail bit number in a power-on operation.

4. The controller of claim 3, wherein the read voltage setting block includes:
an EW counter block configured to output the EW number in the power-on operation;
a retention time prediction block configured to predict a retention time, based on the EW number and the fail bit number; and
a read voltage set setting block configured to select the optimum read voltage set among the plurality of read voltage sets, based on the predicted retention time and the EW number.

5. The controller of claim 4, wherein the retention time prediction block predicts the retention time, based on the EW number and the fail bit number, by using a correlation table including the EW number, the retention time, and the fail bit number.

6. The controller of claim 5, further comprising a buffer memory configured to store the correlation table and the read retry table.

7. A memory system comprising:
a memory device; and
a controller configured to control the memory device to perform a read operation on a target memory area of the memory device in response to a read command received from a host,
wherein the controller selects an optimum read voltage set, based on an erase write cycling (EW) number of the target memory area and a fail bit number of read data corresponding to the read operation.

8. The memory system of claim 7, wherein the controller:
predicts a retention time, based on the EW number and the fail bit number; and
selects the optimum read voltage set among a plurality of read voltage sets in a read retry table, based on the predicted retention time and the EW number.

9. The memory system of claim 8, wherein the memory device includes a system block configured to store the read retry table and a correlation table including the EW number, the retention time, and the fail bit number.

10. The memory system of claim 9, wherein the controller predicts the retention time, based on the EW number and the fail bit number in the correlation table.

11. The memory system of claim 7, wherein the controller includes:
a processor configured to control the read operation in response to the read command; and
an error correction circuit configured to perform an error correction operation of the read data.

12. The memory system of claim 11, wherein the processor includes:
a flash translation layer configured to generate a command queue for controlling the read operation in response to the read command; and
a read voltage set setting block configured to select and set the optimum read voltage set, based on the EW number and the fail bit number in a power-on operation.

13. The memory system of claim 12, wherein the read voltage setting block includes:
an EW counter block configured to output the EW number in the power-on operation;
a retention time prediction block configured to predict a retention time, based on the EW number and the fail bit number; and
a read voltage set setting block configured to select the optimum read voltage set among the plurality of read voltage sets, based on the predicted retention time and the EW number.

14. A method for operating a memory system including a memory device, the method comprising:
determining a fail bit number by performing a read operation on a target memory area of the memory device; and
selecting an optimum read voltage set among a plurality of read voltage sets in a read retry table, based on an erase write cycling (EW) number of the target memory area and the fail bit number.
determining a fail bit number by performing a read operation on a target memory area of the memory device; and selecting an optimum read voltage set among a plurality of read voltage sets in a read retry table, based on an erase write cycling (EW) number of the target memory area and the fail bit number.

15. The method of claim 14, wherein the selecting of the read voltage set includes:
predicting a retention time, based on the EW number and the fail bit number; and
selecting the optimum read voltage set among the plurality of read voltage sets, based on the predicted retention time and the EW number.

16. The method of claim 15, wherein the read retry table includes the plurality of read voltage sets according to the retention time and the EW number.

17. The method of claim 15, wherein the predicting of the retention time comprises predicting the retention time based on a correlation table including the EW number, the fail bit number, and the retention time.

18. The method of claim 17, wherein the correlation table and the read retry table are stored in the memory device, and are read in a power-on operation then stored in a controller.

19. The method of claim 14, further comprising, after the optimum read voltage set is selected, performing a read retry operation on the memory device.
